(19) United States
(12) Patent Application Publication
(10) Pub. No.: US 2013/0002334 A1
(43) Pub. Date: Jan. 3, 2013

(54) INTEGRATED CIRCUIT, ELECTRONIC DEVICE AND METHOD FOR CONFIGURING A SIGNAL PATH FOR A TIMING SENSITIVE SIGNAL

(75) Inventors: Michael Priel, Hertzelia (IL); Leonid Fleshel, Hertzelia (IL); Anton Rozen, Gedera (IL)

(73) Assignee: Freescale Semiconductor, Inc., Austin, TX (US)

(21) Appl. No.: 13/634,992

(22) PCT Filed: Mar. 22, 2010
(86) PCT No.: PCT/IB10/51229

§ 371 Date: Sep. 14, 2012

(51) Int. Cl. H03K 17/00

(52) U.S. Cl. 327/403

(57) ABSTRACT

An integrated circuit comprising at least one signal path for a timing sensitive signal. At least one section of the signal path comprises a first section path comprising a first propagation timing factor, at least one further section path comprising a second propagation timing factor different to the first propagation timing factor, and a path selection component arranged to enable the selection of one of the first and at least one further section paths via which the timing sensitive signal is to propagate through the at least one section of the signal path based on at least one from a group consisting of: the first propagation timing factor, second propagation timing factor.

### FIELD OF THE INVENTION

The field of this invention relates to an integrated circuit, an electronic device and a method for configuring a signal path for a timing sensitive signal.

### BACKGROUND OF THE INVENTION

In the field of electronic devices, and in particular the field of synchronous digital systems, it is known for a clock signal to be used to define a timing reference for a transition of states within functional logic blocks. As such it is known to implement a clock distribution network, sometimes referred to as a clock tree when comprising a general tree-like form, which typically receives one or more clock signals as inputs, and manipulates and distributes the received clock signal(s) to functional logic blocks within a time-synchronous system.

In order for such synchronous systems to function correctly, it is important for the timing of such clock signals that are provided to the various functional logic blocks of the synchronous system to be as accurate as possible, in order to provide the functional logic blocks with an accurate timing reference. Accordingly, great care needs to be taken when designing the signal paths within the clock distribution network, through which the clock signals propagate, in order to ensure proper synchronisation of the various functional logic blocks.

Furthermore, functional logic blocks within synchronous digital systems are not limited to ‘clocked’ components whose output state is updated upon each active edge of a received clock signal, such as a flip-flop or the like. Functional logic blocks within synchronous digital systems typically also comprise ‘transparent’ components whose output states are not dependent upon being updated on active edges of a clock signal. Such transparent components may include, by way of example, combinational logic components such as AND gates, OR gates, etc. A synchronous digital system may comprise many transparent signal paths between clocked components, for example within or between functional logic blocks of the synchronous system, whereby such transparent signal paths comprise various non-clocked, transparent components. A clock distribution network may also comprise transparent signal paths through which clock signals propagate.

Typically, such transparent signal paths comprise a set-up time requirement, whereby a state transition is required to propagate through the transparent signal path and to arrive at its target component, for example an input of a flip-flop or the like, before a particular point in time, for example relative to a clock signal. In this manner, any state transition may be set to occur early enough to be read/sampled by its target component. Furthermore, such transparent signal paths typically comprise a hold time requirement, whereby a state is required to be held at the target component until a particular point in time, for example relative to a clock signal. In this manner, the target component is provided with sufficient time to read/sample the current signal state. If a state transition arrives at its target component too early, the signal state may change before the target component has read/sampled the previous state, thereby corrupting the signal and causing a hold time violation. Conversely, if a state transition arrives at its target component too late, the target component may read/sample the signal state before the state transition has reached it, thereby also corrupting the signal and causing a set-up time violation. Accordingly, great care needs to be taken when designing such transparent signal paths within a synchronous system through which signals propagate, in order to ensure accurate set-up and hold timings.

A significant problem encountered during design and production of integrated circuit devices includes variations in the nominal doping concentrations, and other parameters, during fabrication of the integrated circuit devices on a silicon wafer. Such variations may occur due to minor variations in humidity or temperature during fabrication, or simply due to a position of an individual integrated circuit device within the silicon wafer. Such variations in the fabrication of integrated circuit devices affect on the performance characteristics of components within the integrated circuit devices, and specifically may affect the propagation of signals through their respective signal paths. As a result, even if great care is taken during the design of an integrated circuit device to provide suitable signal paths for timing sensitive signals, the variations in the fabrication of integrated circuit devices can often result in the performance characteristics of components within the signal paths being affected to such a degree that the integrated circuit device is unable to operate at the intended frequency, without set-up and/or hold timing violations occurring and/or without incurring clock synchronisation problems. This problem is particularly relevant to high performance devices required to operate at high frequencies, and may limit the maximum operating frequency for many devices.

The need for accurate synchronisation of transparent signal paths is particularly important where, for example, a functional logic block within an integrated circuit device is dependent on multiple inputs to that functional logic block, and may also comprise multiple internal transparent signal paths that terminate at a common target component, such as an output buffer or the like. Accordingly great care needs to be taken when designing such transparent signal paths within functional logic blocks in order to ensure that the set-up and hold timings for each of the individual signal paths that terminate at the common target component are synchronised.

Another area where the need for accurate synchronisation of transparent signal paths is of particular importance is in a scenario when signals from/to of functional elements such as, by way of example, memory modules that employ double date rate (DDR) techniques, are sampled on both the rising and falling edges of a clock signal. As a result, because signals are sampled twice during each clock cycle, the set-up and hold times are effectively halved, thereby requiring even greater accuracy in their signal paths.

An insertion of buffers has been previously used to enable a plurality of signal paths to be synchronised. However, modern integrated circuit devices are required to provide ever-increasing high performance. As a consequence, integrated circuit devices are typically required to operate at increasingly higher frequencies. Such higher frequency operation requires increasingly accurate clock signals and increasingly strict set-up and hold timing requirements for transparent signal paths. It is known that lenient set-up requirements may limit a maximum achievable performance of the design, whilst lenient hold requirements may not only require extensive buffer insertion, but additionally may limit a maximum achievable performance due to additional hold buffers. Accordingly, the insertion of buffers in this manner results in undesirable delays in the propagation of the signals, leading to timing or hold set-up violations, or in an undesirable reduction in the operating frequency of the circuits. Furthermore, the complexity of modern integrated circuits makes the insertion of such buffers extremely complicated due to the knock-on effect their inclusion can have on the synchronisation of other parts of the circuit.

### SUMMARY OF THE INVENTION

The present invention provides an integrated circuit, an electronic device and a method for configuring a signal path for a timing sensitive signal as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 illustrates an example of a simplified block diagram of part of an electronic device.

FIG. 2 illustrates an example of a synchronous digital system.

FIG. 3 illustrates an example of part of a signal path for a timing sensitive signal.

FIG. 4 illustrates an example of a simplified flowchart of a method for configuring a signal path for a timing sensitive signal.

### DETAILED DESCRIPTION

Because the illustrated embodiments of the present invention may for the most part, be implemented using electronic components and circuits known to those skilled in the art, details will not be explained in any greater extent than that considered necessary as illustrated below, for the understanding and appreciation of the underlying concept of the present invention and in order not to obfuscate or distract from the teachings of the present invention.

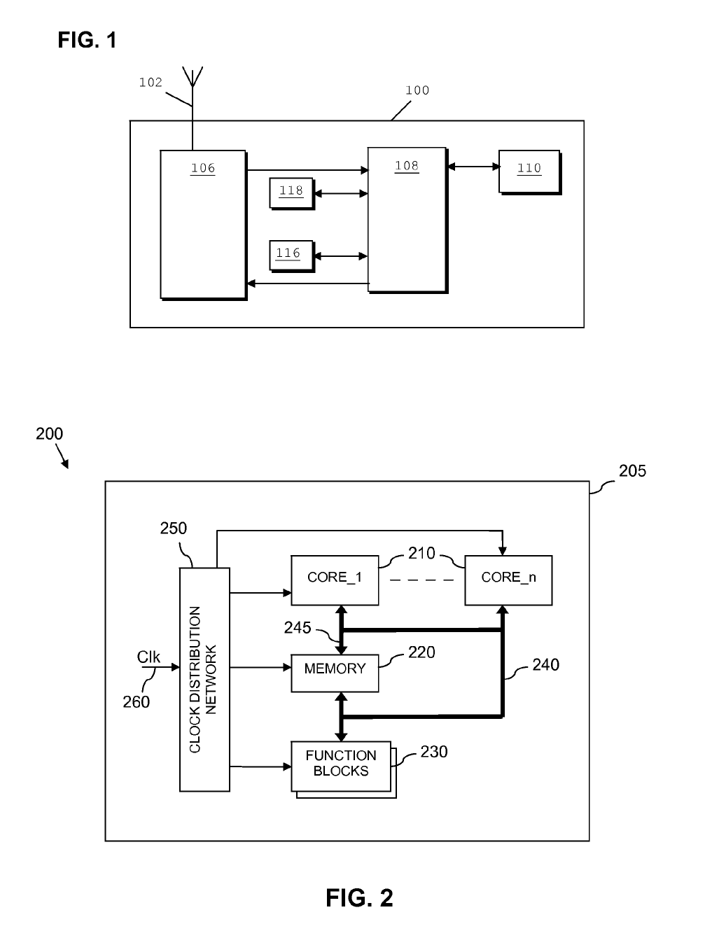

Referring to FIG. 1, there is illustrated an example of a simplified block diagram of part of an electronic device 100, such as may be adapted to support the inventive concept of an example of the present invention. The electronic device 100, in the context of the illustrated embodiment of the invention, is a mobile telephone handset comprising an antenna 102. As such, the communication unit in a form of a mobile telephone handset contains a variety of well known radio frequency components or circuits 106, operably coupled to the antenna 102 that will not be described further herein. The electronic device 100 further comprises signal processing module 108. An output from the signal processing module 108 is provided to a suitable user interface (UI) 110 comprising, for example, one or more of: a display, keypad, microphone, speaker etc. For completeness, the signal processing module 108 is coupled to a memory element 116 that stores operating regimes, such as decoding/encoding functions and the like and may be realised in a variety of technologies such as random access memory (RAM) (volatile), (non-volatile) read only memory (ROM), Flash memory or any combination of these or other memory technologies. A timer 118 is typically coupled to the signal processing module 108 to control the timing of operations within a communication unit 100.

Electronic devices, such as the mobile telephone handset illustrated in FIG. 1 typically comprise one or more synchronous digital systems, such as for example the signal processing module 108, digital signal processing circuits (not shown), etc. Typically, such synchronous digital systems are provided by way of one or more integrated circuit devices.

FIG. 2 illustrates an example of a synchronous digital system 200, and as may be used to implement a synchronous digital system within an electronic device, such as for example the signal processing module 108 of FIG. 1.

For the example illustrated in FIG. 2, the synchronous digital system 200 is implemented within an integrated circuit device 205. The synchronous digital system 200 comprises various functional logic blocks, which for the illustrated example comprises a plurality of processing cores 210, a memory element 220, and various other function blocks 230, such as a generic arithmetic logic unit (ALU), video processing unit, graphical processing unit, etc. The various functional logic blocks 210, 220, 230, of the synchronous digital system 200 may be operably coupled to one another in a variety of manners, for example by way of address/data buses, control signal paths, interrupt signal paths, etc, as illustrated generally by arrows 240. The synchronous digital system 200 further comprises a clock distribution network 250 arranged to manipulate and distribute one or more received clock signal(s) 260 to the functional logic blocks 210, 220, 230 within the synchronous digital system 200.

Synchronous digital systems, such as the example illustrated in FIG. 2, typically comprise and support a large number of timing sensitive signals. Such timing sensitive signals may comprise, by way of example, clock signals within the clock distribution network 250, as well as internal signals within the functional logic blocks 210, 220, 230 and inter-functional logic block signals, such as those provided over signal paths 240 that propagate through transparent signal paths and comprise strict set-up and hold timing constraints. A problem encountered during a design and production of integrated circuit devices includes variations in the nominal doping concentrations and other parameters during fabrication of the integrated circuit devices on a silicon wafer. Such variations may occur due to minor variations in humidity or temperature during fabrication, or simply due to a location of individual integrated circuit device within the silicon wafer. Such variations in the fabrication of integrated circuit devices may have an effect on the performance characteristics of transistors and the like within the integrated circuit devices, and specifically may affect the propagation of signals through their respective signal paths. The performance characteristics typically depend upon various parameters, including, by way of example, threshold voltage, mobility, oxide width, etc.

In accordance with some examples, the integrated circuit 205 comprises at least one signal path for a timing sensitive signal wherein at least one section of the signal path comprises a first section path comprising a first propagation timing factor, at least one further section path comprising a second propagation timing factor different to the first propagation timing factor, and a path selection component arranged to enable a selection of one of the first and at least one further section paths via which the timing sensitive signal is to propagate through the at least one section of the signal path, based on at least one of the first or second propagation timing factors.

In this manner, the signal path for the timing sensitive signal may be configured post-fabrication of the integrated circuit device 205 by selecting which of the section paths the timing sensitive signal is to propagate through. Significantly, by providing section paths comprising different propagation timing factors (as described in greater detail below), the amount of time taken for the signal to propagate through the timing path may be configured based on which of one or more section path is/are selected. Thus, variations in the fabrication of such integrated circuit devices that affect the propagation of signals through their respective signal paths may be at least partially compensated for, post-fabrication. As a result, integrated circuit devices suffering from such variations in the fabrication process may still be able to operate at faster frequencies than would be the case for prior art integrated circuit devices by appropriate configuration of the signal paths for the timing sensitive signals, and may even be able to be adjusted/selected to operate at their intended frequencies.

The need for accurate synchronisation of signal paths is particularly important where, for example, a functional logic block within an integrated circuit device is dependent on multiple inputs to that functional logic block, and comprises multiple internal transparent signal paths that terminate at a common target component, such as an output buffer or the like. Accordingly great care needs to be taken when designing such transparent signal paths within functional logic blocks in order to ensure that the set-up and hold timings for each of the individual signal paths that terminate at the common target component are synchronised. Another area where the need for accurate synchronisation of transparent signal paths is of particular importance is in the case of functional elements such as, by way of example, memory modules that employ double date rate (DDR) techniques whereby signals are sampled on both the rising and falling edges of a clock signal. As a result, because signals are sampled twice during each clock cycle, the set-up and hold times are effectively halved, requiring even greater accuracy in their signal paths. Accordingly, signal paths configured in some examples may comprise internal signal paths within one or more of the functional logic blocks 210, 220, 230, memory interface signal paths such as indicated generally at 240, and/or one or more inter-functional logic block signal paths 240. Furthermore, it is contemplated that example signal path routes configured as being selectable may additionally/alternatively comprise signal paths within the clock distribution network (250).

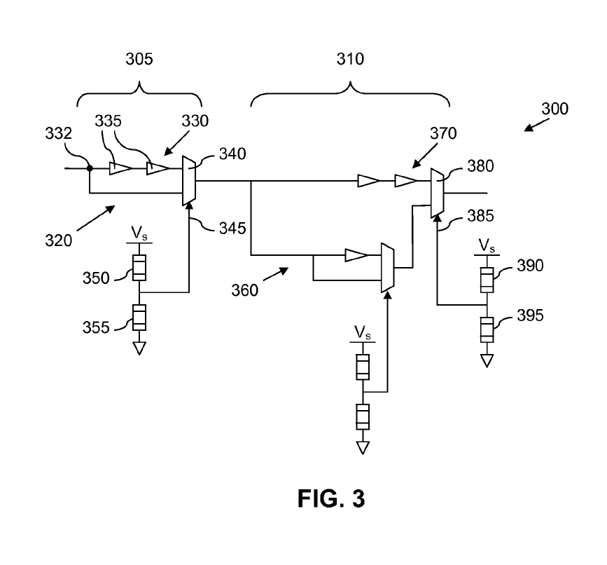

Referring now to FIG. 3, there is illustrated an example of part of a selectable signal path 300 for a timing sensitive signal configured in accordance with some examples. A first section 305 of the signal path 300 comprises a first section path, illustrated generally at 320, comprising a first propagation timing factor. The first section 305 of the signal path 300 comprises a second section path, illustrated generally at 330, comprising a second propagation timing factor different to the first propagation timing factor of the first section path 320. The first section 305 further comprises a path selection component, which for the illustrated example comprises a multiplexer device 340, arranged to enable a selection of one of the section paths 320, 330 via which the timing sensitive signal is to propagate through the first section 305 of the signal path 300. Examples of the present invention are not limited to a use of a multiplexer device 340 for implementing the path selection component, and it is envisaged that any other suitable arrangement may be used. For example, a composition of combinational logic components, such as AND gates, OR gates, etc. may alternatively be used.

For the illustrated example, the first section path 320 comprises a conductive path such as a conductive track or wire operably coupled between a section node 332 and a first input of the multiplexer device 340. Accordingly, the time taken for a signal to propagate through the first section path 320 from the section node 332 to the multiplexer device 340 is dependent on the conductive properties of the conductive path of which the first section path 320 is comprised and a voltage and/or current source driving the signal.

Conversely, the second section path 330 of the illustrated example comprises delay elements 335 operably coupled in series between the section node 332 and a second input of the multiplexer device 340; the delay elements 335 being operably coupled by way of conductive paths, such as further conductive tracks and/or wires, etc. Accordingly, the time taken for a signal to propagate through the second section path 330 from the section node 332 to the multiplexer device 340 is dependent upon the transition characteristics of the delay elements 335, the conductive properties of the conductive tracks and/or wires coupling the delay elements 335, and a voltage and/or current source driving the signal.

In other examples the propagation of the signal through the second section path 330 may be performed substantially by the same function on the signal as the propagation of the signal through the first section path 320. In this manner, substantially the only difference between the propagation of the signal through the different section paths is time taken for the signal to propagate there through.

Thus, the first section path 320 for the illustrated example may be considered to comprise a first propagation timing factor derived from the conductive properties of the conductive path of which the first section path 320 is comprised. Conversely, the second section path 330 for the illustrated example may be considered to comprise a second propagation timing factor derived from the transition characteristics of the delay elements 335, and the conductive properties of the conductive tracks and/or wires coupling the delay elements 335. In this manner, the first and second section paths 320, 330 comprise different propagation timing factors. Thus, the signal path 300 selected for the timing sensitive signal may be configured by selecting via which of the section paths 320 or 330 the timing sensitive signal is to propagate through the first section 305 thereof. Significantly, by providing the section paths 320, 330 with different propagation timing factors, the amount of time taken for the signal to propagate through the timing path for a defined voltage and/or current source driving the signal may be configured based on which section path 320, 330 is selected. Typically, such propagation timing factors are most significantly influenced by parasitic capacitances, parasitic resistance, characteristics of driving transistors, etc.

The multiplexer device 340 is arranged to receive a control signal 345 and to select one of the section paths 320, 330 in accordance with the received control signal 345 to operably couple to an output thereof, and thereby via which the timing sensitive signal is to propagate through the first section 305 of the signal path 300. In this manner, the signal path 300 may be at least partly configured by way of the control signal 345.

For the illustrated example, the control signal 345 is operably coupled to a first voltage signal (Vs) via a first configuration element 350 and to a second reference voltage, which for the illustrated example comprises a ground plane (e.g. 0 v) via a second configuration element 355. For the illustrated example, the configuration elements 350, 355 are initially configured to couple their respective voltage signals to the control signal 345, and are arranged to be subsequently configurable to decouple their respective voltage signals from the control signal 345. For example, each configuration element 350, 355 may comprise a fuse, flip-flop output or any other logical function. In this manner, one of the first and second configuration elements 350, 355 of the illustrated example may be configured post-fabrication to decouple its respective voltage signal from the control signal 345, thereby enabling the voltage applied to the control signal 345 to be configurable post-fabrication. In this manner, the selection of the section paths 320, 330 by the multiplexer device 340 is configurable post-fabrication, and thereby the first section 305 of the signal path 300 may be dynamically configured post-fabrication, for example during a post-fabrication product test of the integrated circuit device 205, by way of dynamic re-configuration of signal paths in a post-fabrication process, that may in some examples be dependent upon an application that the integrated circuit device 205 is to be applied to, etc.

Each section path may comprise any number of delay elements, or other ‘transparent’ components whose output states are not dependent upon being updated on active edges of a clock signal. Such transparent components may include, by way of example, combinational logic components such as AND gates, OR gates, etc. Furthermore, a path section is not limited to comprising only two selectable section paths, but may comprise any number of two or more selectable section paths, each comprising any number of logic components that provide an influence on a timing factor for that signal path.

Furthermore, a signal path adapted in accordance with some embodiments of the present invention is not limited to only a single section being configurable as described above. For example, and as illustrated in FIG. 3, the signal path 300 may comprise one or more further sections arranged in series, such as section 310 or arranged in parallel (not shown). Section 310 comprises a first selectable section path 360 comprising a first propagation timing factor, at least one further selectable section path 370 comprising a second propagation timing factor different to the first propagation timing factor of the first section path 360. A path selection component 380 is arranged to enable a selection of one of the first and at least one further section paths 360, 370, via which the timing sensitive signal is to propagate through the second section 310 of the signal path 300. Thus, in this manner, the propagation of the time sensitive signal through the signal path 300 may be configurable for multiple sections 305, 310 of the signal path 300, thereby allowing for greater flexibility in the configuration of the propagation of the signal there through.

For the illustrated example, the path selection component 380 of the second section also comprises a multiplexer device arranged to receive a control signal 385 and to select one of the section paths 360, 370 in accordance with the received control signal 385 to operably couple to an output thereof, and thereby via which the timing sensitive signal is to propagate through the further section 310 of the signal path 300. Furthermore, the control signal 385 is also operably coupled to a first reference voltage (or voltage signal (Vs)) via a first configuration element 390 and to a second reference voltage (or second voltage signal), which for the illustrated example comprises a ground plane (e.g. 0 v) via a second configuration element 395, in a similar manner as for the control signal 345 for the multiplexer device 340 of the first section 305.

It is also contemplated that configurable propagation paths may be nested within sections of a signal path. For example, and as illustrated in FIG. 3, the first section path 360 comprises a nested configurable section of the signal path 300. In this manner, still further flexibility may be provided within the configurability of a selectable propagation path having a particular time factor for a time sensitive signal.

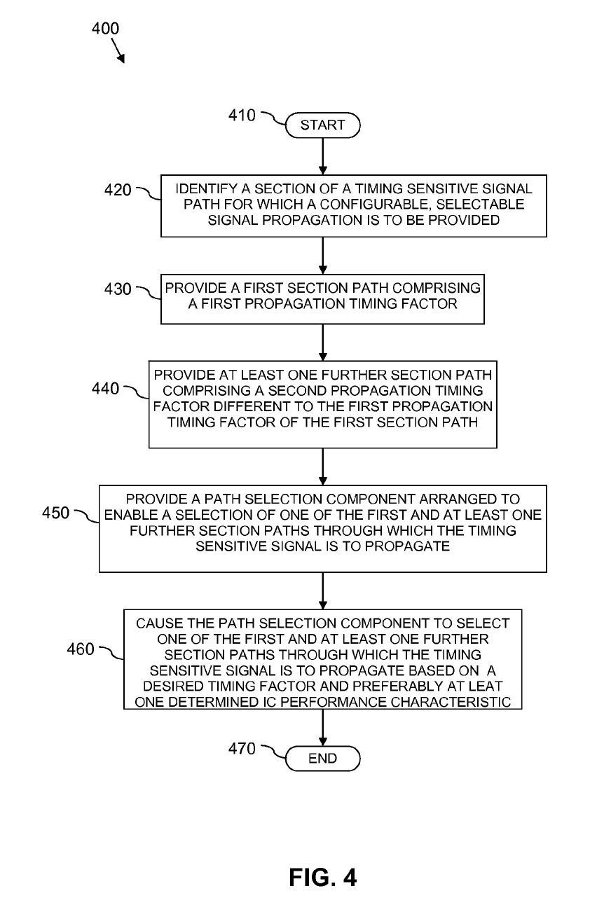

Referring now to FIG. 4, there is illustrated an example of a simplified flowchart 400 of a method for configuring a signal path for a timing sensitive signal within an integrated circuit. The method starts at step 410, and moves on to step 420 where a section of a signal path for a timing sensitive signal for which a configurable, selectable signal propagation is to be provided is identified. A first section path comprising a first propagation timing factor is provided for the identified section at step 430. At least one further section path comprising a second propagation timing factor, different to the first propagation timing factor of the first section path is then provided for the identified section at step 440. At step 450, a path selection component arranged to enable a selection of one of the first and at least one further section paths via which the timing sensitive signal is to propagate through the identified section of the signal path is provided. The path selection component is subsequently caused to select one of the first and at least one further section paths via which the timing sensitive signal is to propagate based on a desired timing factor, and preferably at least one determined performance characteristic for the integrated circuit device, at step 460. The method then ends at step 470. In some examples when implementing the method of FIG. 4, steps 420 to 450 may be performed within a design and fabrication processes for the production of an integrated circuit, whilst step 460 may be performed post-fabrication of the integrated circuit device.

In this manner, the signal path for the timing sensitive signal may be configured post-fabrication of the integrated circuit device, by selecting which of the section paths the timing sensitive signal is to propagate through, based on respective different propagation timing factors of various signal paths. In one example, the selection of the section path may also be based on at least one determined performance characteristic integrated circuit device. Significantly, by providing section paths comprising different propagation timing factors, the amount of time taken for the signal to propagate through the respective path may be configured based on which section path is selected. Thus, variations in the fabrication process of such integrated circuit devices, that may affect the propagation of signals through their respective signal paths, may be at least partially compensated for post-fabrication. As a result, integrated circuit devices suffering from such variations in the fabrication process may still be able to operate at faster frequencies than would be the case for prior art devices by appropriate configuration and selection of the signal paths for the timing sensitive signals, and may even be able to operate at their intended frequencies.

The selection of one of the section paths via which the timing sensitive signal is to propagate in step 460 is based on at least one determined performance characteristic for the integrated circuit device. Such performance characteristics may comprise any suitable characteristic relevant to the propagation of signals within the integrated circuit device. For example, such a performance characteristic may comprise a process corner of the integrated circuit device, production test measurements, etc, or a combination of such characteristics.

Examples of the invention, for example the signal path selection process, may also be implemented in a computer program for running on a computer system, at least including code portions for performing steps of a method according to the invention when run on a programmable apparatus, such as a computer system or enabling a programmable apparatus to perform functions of a device or system according to the invention.

A computer program is a list of instructions such as a particular application program and/or an operating system. The computer program may for instance include one or more of: a subroutine, a function, a procedure, an object method, an object implementation, an executable application, an applet, a servlet, a source code, an object code, a shared library/dynamic load library and/or other sequence of instructions designed for execution on a computer system.

The computer program may be stored internally on computer readable storage medium or transmitted to the computer system via a computer readable transmission medium. All or some of the computer program may be provided on computer readable media permanently, removably or remotely coupled to an information processing system. The computer readable media may include, for example and without limitation, any number of the following: magnetic storage media including disk and tape storage media; optical storage media such as compact disk media (e.g., CD-ROM, CD-R, etc.) and digital video disk storage media; non-volatile memory storage media including semiconductor-based memory units such as FLASH memory, electrically erasable programmable read only memory (EEPROM), electrically programmable read only memory (EPROM), read only memory (ROM); ferromagnetic digital memories; magnetic random access memory (MRAM); volatile storage media including registers, buffers or caches, main memory, RAM, etc.; and data transmission media including computer networks, point-to-point telecommunication equipment, and carrier wave transmission media, just to name a few.

A computer process typically includes an executing (running) program or portion of a program, current program values and state information, and the resources used by the operating system to manage the execution of the process. An operating system (OS) is the software that manages the sharing of the resources of a computer and provides programmers with an interface used to access those resources. An operating system processes system data and user input, and responds by allocating and managing tasks and internal system resources as a service to users and programs of the system.

The computer system may for instance include at least one processing unit, associated memory and a number of input/output (I/O) devices. When executing the computer program, the computer system processes information according to the computer program and produces resultant output information via I/O devices.

In the foregoing specification, the invention has been described with reference to specific examples of embodiments of the invention. It will, however, be evident that various modifications and changes may be made therein without departing from the broader spirit and scope of the invention as set forth in the appended claims.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connections that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will be appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “de-assert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediary components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one, or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. An integrated circuit comprising at least one signal path for a timing sensitive signal, wherein at least one section of the signal path comprises:
a first section path comprising a first propagation timing factor;
at least one further section path comprising a second propagation timing factor different to the first propagation timing factor; and
a path selection component arranged to enable a selection of one of the first and at least one further section paths via which the timing sensitive signal is to propagate through the at least one section of the signal path based on at least one from a group consisting of: the first propagation timing factor, second propagation timing factor.

2. The integrated circuit of claim 1 wherein the path selection component is arranged to enable a selection of one of the first and at least one further section paths further based on at least one performance characteristic of the integrated circuit.

3. The integrated circuit of claim 1 wherein the path selection component comprises a multiplexer device, and the first and at least one further section paths are operably coupled to inputs of the multiplexer device; wherein the multiplexer device is arranged to receive a control signal and in response thereto select one of the first and at least one further section paths to operably couple to an output of the multiplexer device.

4. The integrated circuit of claim 3 wherein the control signal provided to the multiplexer device is capable of being configured to comprise one of a first reference voltage and at least one further reference voltage by way of at least one configuration element to select a signal path.

5. The integrated circuit of claim 1 wherein at least one of the first and at least one further section paths comprises at least one delay element for causing a delay in a propagation of a signal there through.

6. The integrated circuit of claim 1 wherein the signal path for the timing sensitive signal comprises at least one from a group consisting of:
an internal signal path within a functional logic block;
a buffer;
a memory interface signal path;
an inter-functional logic block signal path;
a signal path within a clock distribution network.

7. The integrated circuit of claim 1 wherein the signal path for the timing sensitive signal is configured to support double data rate sampling.

8. An electronic device comprising an integrated circuit device comprising an integrated circuit comprising at least one signal path for a timing sensitive signal, wherein at least one section of the signal path comprises:
a first section path comprising a first propagation timing factor;
at least one further section path comprising a second propagation timing factor different to the first propagation timing factor; and
a path selection component arranged to enable the selection of one of the first and at least one further section paths via which the timing sensitive signal is to propagate through the at least one section of the signal path based on at least one from a group consisting of: the first propagation timing factor, second propagation timing factor.

9. A method for configuring a signal path for a timing sensitive signal within an integrated circuit, the method comprising:
providing at least one section of the signal path with a first section path comprising a first propagation timing factor;
providing the at least one section of the signal path with at least one further section path, the at least one further section path comprising a propagation timing factor different to the first propagation timing factor;
providing a path selection component arranged to enable the selection of one of the first and at least one further section paths via which the timing sensitive signal is to propagate through the at least one section of the signal path; and
causing the path selection component to select one of the first and at least one further section paths via which the timing sensitive signal is to propagate based on at least one from a group consisting of: the first propagation timing factor, second propagation timing factor, at least one performance characteristic for the integrated circuit device.
